(19) United States
(12) Patent Application Publication
(10) Pub. No.: US 2025/0093758 A1
(43) Pub. Date: Mar. 20, 2025

(54) LIQUID COOLING MODULE AND PROJECTION DEVICE

(71) Applicant: Coretronic Corporation, Hsin-Chu (TW)

(72) Inventors: Chun-Ting Lin, Hsin-Chu (TW); Wen-Yen Chung, Hsin-Chu (TW)

(73) Assignee: Coretronic Corporation, Hsin-Chu (TW)

(21) Appl. No.: 18/822,436

(22) Filed: Sep. 2, 2024

(30) Foreign Application Priority Data
Sep. 15, 2023 (CN) 202311191292.7

(51) Int. Cl. G03B 21/16; H05K 7/20

(52) U.S. Cl. CPC G03B 21/16; H05K 7/20154; H05K 7/20263; H05K 7/20272

(57) ABSTRACT

A liquid cooling module is used to cool a lighting module. The liquid cooling module includes a first cooling unit, a second cooling unit, a heat dissipation component and a pipeline component. The first cooling unit includes a first communication surface and a first cooling surface. The second cooling unit includes a top surface, a second communication surface and a second cooling surface. The top surface is perpendicular to the first communication surface and opposite to the second cooling surface. The pipeline component includes a first pipeline, a second pipeline and a third pipeline. The first pipeline is connected to the heat dissipation component and the first communication surface, the second pipeline is connected to the first communication surface and the second communication surface, and the third pipeline is connected to the second communication surface and the heat dissipation component. In addition, a projection device is also mentioned.

### CROSS-REFERENCE TO RELATED APPLICATION

This application claims the priority benefit of China application serial no. 202311191292.7, filed on Sep. 15, 2023. The entirety of the above-mentioned patent application is hereby incorporated by reference herein and made a part of this specification.

### BACKGROUND

### Technical Field

The disclosure relates to a cooling module and a display device, and in particular relates to a liquid cooling module and a projection device.

### Description of Related Art

As modern projection devices strive for higher brightness and resolution, the wattage of the light source of the projection device increases, the heat emitted by the heat-generating components increases, and the number of lenses in the lens module increases. This raises the internal heat energy of the projection device. Additionally, the reduction of internal space within the projection device further compresses the heat dissipation space of the projection device. This reduces the heat dissipation efficiency of the projection device such that the projection device easily overheats. In addition, in order to solve the problem of increased heat energy inside the projection device, multiple fans are installed and the speed of these fans is increased to enhance heat dissipation. However, this solution introduces the issue of noise pollution.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the disclosure was acknowledged by a person of ordinary skill in the art.

### SUMMARY

A liquid cooling module and a projection device, which have good heat dissipation performance and reduce the noise generated by the fan speed, are provided in the disclosure.

The other objectives and advantages of the disclosure may be further understood from the descriptive features disclosed in the disclosure.

In order to achieve one of, or portions of, or all of the above objectives or other objectives, the liquid cooling module is configured to cool a lighting module. The liquid cooling module includes a first cooling unit, a second cooling unit, a heat dissipation component, and a pipeline component. The first cooling unit includes a first communication surface and a first cooling surface opposite to the first communication surface, and the first cooling surface is connected to a first heat source of the lighting module. The second cooling unit includes a top surface, a second communication surface, and a second cooling surface. The top surface is perpendicular to the first communication surface and opposite to the second cooling surface, and the second cooling surface is connected to a second heat source of the lighting module. The heat dissipation component is configured to dissipate heat from a heat dissipation medium. The heat dissipation medium flows in the pipeline component. The pipeline component includes a first pipeline, a second pipeline, and a third pipeline. The first pipeline is connected to the heat dissipation component and the first communication surface, the second pipeline is connected to the first communication surface and the second communication surface, and the third pipeline is connected to the second communication surface and the heat dissipation component.

In an embodiment of the disclosure, the first cooling unit includes a first water inlet and a first water outlet. The first water inlet and the first water outlet are located on the first communication surface, and the first water inlet and the first water outlet are not aligned in a gravity direction. The first water inlet is connected to the first pipeline, and the first water outlet is connected to the second pipeline.

In an embodiment of the disclosure, the first pipeline includes a first sub-pipeline and a second sub-pipeline. The first sub-pipeline is connected to the heat dissipation component and a pump, and the second sub-pipeline is connected to the pump and the first communication surface of the first cooling unit.

In an embodiment of the disclosure, the liquid cooling module is further configured to cool a light valve module, and the liquid cooling module further includes a third cooling unit. The third pipeline includes a third sub-pipeline and a fourth sub-pipeline. The third sub-pipeline is connected to the second cooling unit and the third cooling unit. The fourth sub-pipeline is connected to the third cooling unit and the heat dissipation component. The third cooling unit is connected to the light valve module.

In an embodiment of the disclosure, the heat dissipation component includes a heat sink, and a water tank. The heat sink is connected to the water tank, and a bottom surface of the heat sink and a bottom surface of the water tank are not aligned in a gravity direction to form a first space. A portion of the third pipeline is disposed in the first space and connected to the heat sink, and the first pipeline is connected to the water tank.

In an embodiment of the disclosure, the heat sink and water tank are integrally formed.

In an embodiment of the disclosure, the water tank includes a fin structure.

In an embodiment of the disclosure, the second cooling unit includes a side surface, a second water inlet, and a second water outlet. The second communication surface is the side surface, the second water inlet and the second water outlet are located on the side surface, and the second water inlet and the second water outlet are not aligned in a gravity direction.

In an embodiment of the disclosure, the second cooling unit includes two side surfaces, a second water inlet, and a second water outlet. The second communication surface is the two side surfaces, the second water inlet and the second water outlet are located on the second communication surface, the second water inlet is located on one of the two side surfaces, and the second water outlet is located on another one of the two side surfaces.

In an embodiment of the disclosure, a diameter of the second pipeline is less than a diameter of the first pipeline, and the diameter of the second pipeline is less than a diameter of the third pipeline.

In order to achieve one of, or portions of, or all of the above objectives or other objectives, the projection device of the disclosure includes a lighting module, a light valve module, a lens module, and a liquid cooling module. The lighting module is configured to provide an illumination beam, and the lighting module includes a first heat source and a second heat source. The light valve module is disposed on a transmission path of the illumination beam to convert the illumination beam into an image beam. The lens module is disposed on a transmission path of the image beam to project the image beam. The liquid cooling module includes a first cooling unit, a second cooling unit, a heat dissipation component, and a pipeline component. The first cooling unit includes a first communication surface and a first cooling surface opposite to each other, and the first cooling surface is connected to the first heat source. The second cooling unit includes a top surface, a second communication surface, and a second cooling surface. The top surface is perpendicular to the first communication surface and opposite to the second cooling surface, and the second cooling surface is connected to the second heat source. The heat dissipation component is configured to dissipate heat from a heat dissipation medium. The heat dissipation medium flows in the pipeline component, which includes a first pipeline, a second pipeline, and a third pipeline. The first pipeline is connected to the heat dissipation component and the first communication surface, the second pipeline is connected to the first communication surface and the second communication surface, and the third pipeline is connected to the second communication surface and the heat dissipation component.

In an embodiment of the disclosure, the first cooling unit includes a first water inlet and a first water outlet. The first water inlet and the first water outlet are located on the first communication surface, and the first water inlet and the first water outlet are not aligned in a gravity direction. The first water inlet is connected to the first pipeline, and the first water outlet is connected to the second pipeline.

In an embodiment of the disclosure, the liquid cooling module further includes a pump. The first pipeline includes a first sub-pipeline and a second sub-pipeline. The first sub-pipeline is connected to the heat dissipation component and a pump, and the second sub-pipeline is connected to the pump and the first communication surface of the first cooling unit.

In an embodiment of the disclosure, the first heat source and second heat source are both light source devices, and the first heat source and the second heat source are configured to provide multiple light beams. The lighting module further includes a light combining component. The light combining component is located at a position that receives multiple light beams. The light combining component is configured to guide the light beams to form an illumination beam.

In an embodiment of the disclosure, the liquid cooling module further includes a third cooling unit, and the third pipeline includes a third sub-pipeline and a fourth sub-pipeline. The third sub-pipeline is connected to the second cooling unit and the third cooling unit, the fourth sub-pipeline is connected to the third cooling unit and the heat dissipation component, and the third cooling unit is connected to the light valve module for cooling the light valve module.

In an embodiment of the disclosure, the heat dissipation component includes a heat sink and a water tank, and the heat sink is connected to the water tank. A bottom surface of the heat sink and a bottom surface of the water tank are not aligned in a gravity direction to form a first space. A portion of the third pipeline is disposed in a first space and connected to the heat sink, and the first pipeline is connected to the water tank.

In an embodiment of the disclosure, the second cooling unit includes a side surface, a second water inlet, and a second water outlet, and the second communication surface is the side surface. The second water inlet and the second water outlet are located on the side surface, and the second water inlet and the second water outlet are not aligned in a gravity direction.

In an embodiment of the disclosure, the second cooling unit includes two side surfaces, a second water inlet, and a second water outlet. The second water inlet and the second water outlet are located on the second communication surface. The second communication surface is the two side surfaces. The second water inlet is located on one of the two side surfaces, and the second water outlet is located on another one of the two side surfaces.

In an embodiment of the disclosure, the projection device further includes a casing, at least one intake fan, and at least one exhaust fan. The liquid cooling module, the lighting module, the light valve module, the at least one intake fan, and the at least one exhaust fan are located in the casing. The casing includes at least one air inlet and at least one air outlet, and the at least one intake fan and the at least one exhaust fan are configured to form airflow. The heat dissipation component is located on a path of the airflow for heat exchange with the airflow. The airflow enters the casing from the at least one air inlet and leaves the casing from the at least one air outlet.

In an embodiment of the disclosure, the heat dissipation component is located between the at least one air inlet and the at least one intake fan.

In an embodiment of the disclosure, the projection device further includes a power module and a casing. The casing has a bottom portion, and the power module is located between the lens module and the bottom portion in a gravity direction.

In an embodiment of the disclosure, the projection device further includes a casing, and the casing has a bottom portion. In a gravity direction, a second space is formed between the first cooling unit and the bottom portion and between the second cooling unit and the bottom portion, and a portion of the second pipeline is disposed in the second space.

Based on the above, the first cooling unit of the liquid cooling module of the disclosure and the projection device using the same is configured to cool the first heat source, and the second cooling unit is configured to cool the second heat source. The second pipeline of the pipeline component is connected to the first communication surface of the first cooling unit and the second communication surface of the second cooling unit. The first communication surface and the second communication surface do not affect each other, and the first communication surface is perpendicular to the top surface of the second cooling unit. By transporting the heat dissipation medium through the pipeline component, the liquid cooling module and the projection device may cool the lighting module through liquid cooling, which has good heat dissipation performance and may reduce the volume of the liquid cooling module and the projection device.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

FIG. 1 is a schematic diagram of a projection device according to an embodiment of the disclosure.

FIG. 2 is a top schematic view of the projection device in FIG. 1.

FIG. 3 is a schematic diagram of the liquid cooling module of the projection device of FIG. 2.

FIG. 4 is a partial enlarged diagram of the liquid cooling module of FIG. 3.

FIG. 5 is a schematic diagram of the projection device in FIG. 1 from another viewing angle.

FIG. 6 is a schematic diagram of a projection device according to another embodiment of the disclosure.

### DETAILED DESCRIPTION OF DISCLOSED EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention may be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

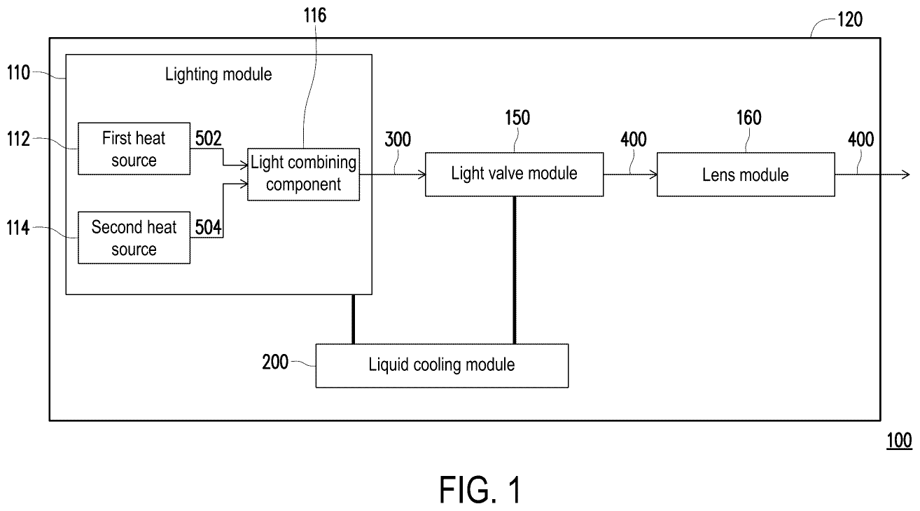

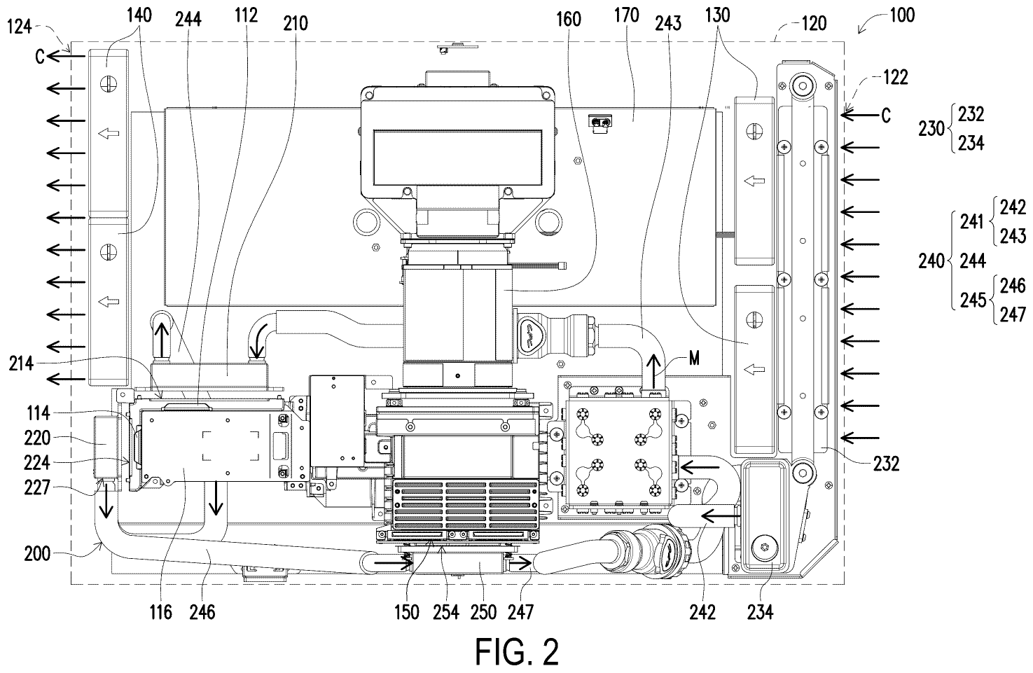

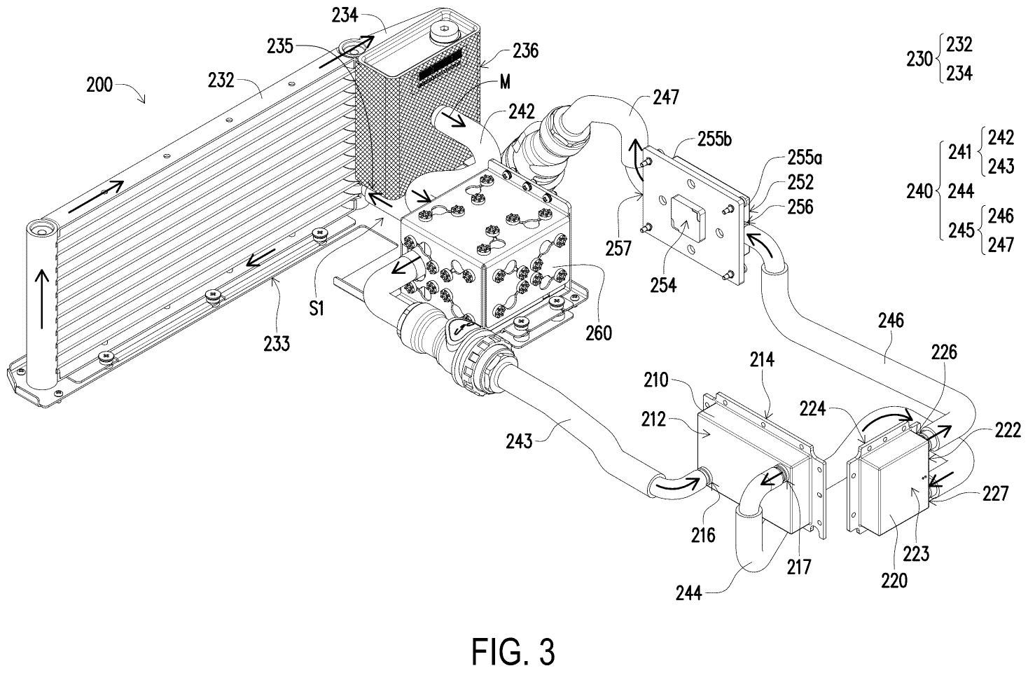

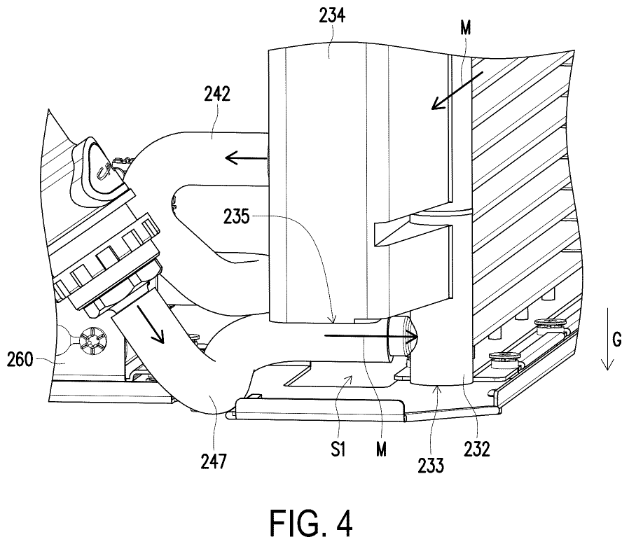

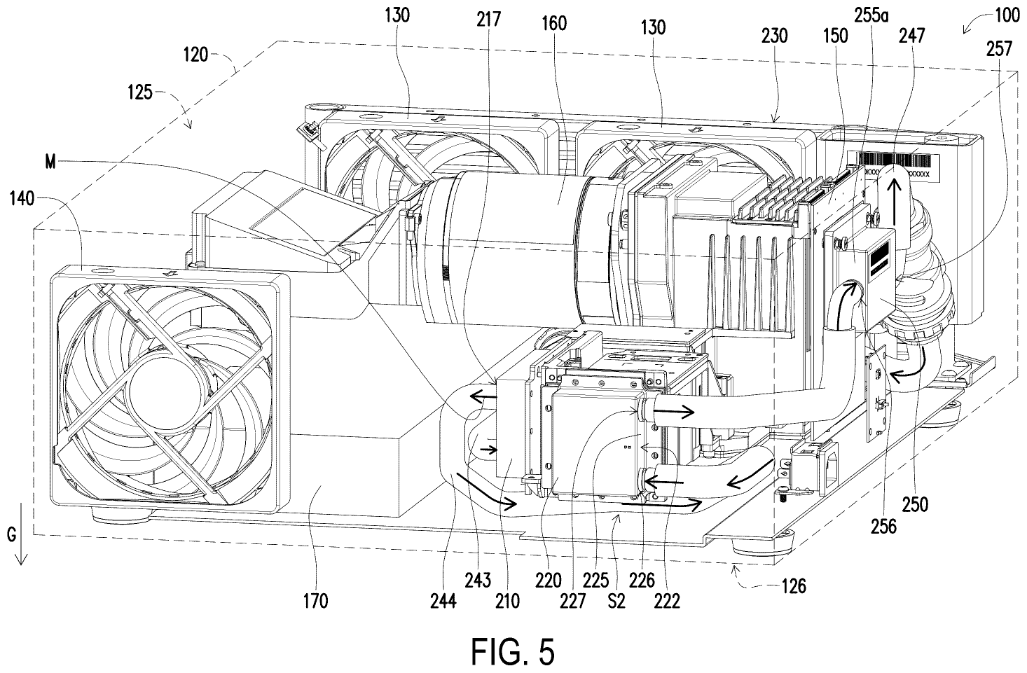

FIG. 1 is a schematic diagram of a projection device according to an embodiment of the disclosure. FIG. 2 is a top schematic view of the projection device in FIG. 1. FIG. 3 is a schematic diagram of the liquid cooling module of the projection device of FIG. 2. FIG. 4 is a partial enlarged diagram of the liquid cooling module of FIG. 3. FIG. 5 is a schematic diagram of the projection device in FIG. 1 from another viewing angle. The projection device 100 in FIG. 5 has two exhaust fans 140, but the drawing of one exhaust fan 140 is omitted herein to avoid obscuring the components inside the projection device 100.

Referring to FIG. 1 to FIG. 5, the projection device 100 includes a casing 120, a lighting module 110, a light valve module 150, a lens module 160, and a liquid cooling module 200. The liquid cooling module 200, the lighting module 110, the light valve module 150, and the lens module 160 are located in the casing 120. The liquid cooling module 200 is configured to cool the lighting module 110 and the light valve module 150. The lighting module 110 is configured to provide an illumination beam 300. The light valve module 150 is disposed on the transmission path of the illumination beam 300 to convert the illumination beam 300 into the image beam 400. The lens module 160 is disposed on the transmission path of the image beam 400 to project the image beam 400 out of the projection device 100.

The light valve module 150 includes, for example, one of a reflective light modulator such as a liquid crystal on silicon panel (LCOS panel) and a digital micro-mirror device (DMD). In some embodiments, the light valve module 150 may also include one of the transmissive optical modulator, such as a transparent liquid crystal panel, an electro-optical modulator, a magneto-optical modulator, or an acousto-optic modulator (AOM), etc. This disclosure does not limit the form and type of the light valve module 150. The detailed process and implementation for the light valve module 150 to convert the illumination beam 300 into the image beam 400 may be obtained from general knowledge in the technical field with sufficient teaching, suggestion and implementation description, and therefore will not be repeated. In this embodiment, the number of light valve module 150 is one, such as a projection device 100 using a single digital micro-mirror element, but in other embodiments there may be more than one light valve module 150, and the disclosure is not limited to this.

The lens module 160 includes, for example, a combination of one or more optical lenses with diopter, such as various combinations of non-planar lenses such as biconcave lenses, biconvex lenses, meniscus lenses, convex-concave lenses, plano-convex lenses, and plano-concave lenses. In one embodiment, the lens module 160 may further include a planar, concave, or convex optical lens to project the image beam 400 to a projection target (e.g., a wall or a projection screen) in a reflective manner. This disclosure does not limit the form and type of the lens module 160.

As shown in FIG. 1 and FIG. 2, the lighting module 110 includes a first heat source 112, a second heat source 114, and a light combining component 116, but not limited thereto. In this embodiment, the first heat source 112 and the second heat source 114 are both light source devices, and the first heat source 112 is configured to provide at least one light beam 502. The second heat source 114 is configured to provide at least one light beam 504. The light source device may include a laser diode or a light emitting diode (LED). The first heat source 112 may include red, green and blue (RGB) laser diodes and another green laser diode, and the second heat source 114 may include red, green and blue laser diodes, but not limited thereto.

The light combining component 116 is, for example, formed of at least one dichroic mirror, but not limited thereto. The light combining component 116 is located at a position to receive multiple light beams 502 and 504. The light combining component 116 is configured to guide the light beams 502 and 504 to form the illumination beam 300. The light combining component 116 of this embodiment may also be used with other optical elements (e.g., lenses) to guide multiple light beams 502 and 504.

As shown in FIG. 2 and FIG. 3, the liquid cooling module 200 includes a first cooling unit 210, a second cooling unit 220, a heat dissipation component 230, a pipeline component 240, and a pump 260. The first cooling unit 210 and the second cooling unit 220 are respectively configured to dissipate heat from the first heat source 112 and the second heat source 114 of the lighting module 110. The pipeline component 240 is configured to connect the various parts of the liquid cooling module 200 (first cooling unit 210, second cooling unit 220, third cooling unit 250, pump 260, and heat dissipation component 230). The heat dissipation medium M flows in the pipeline component 240. The heat dissipation medium M performs heat exchange with the first heat source 112 and the second heat source 114 through heat conduction in the first cooling unit 210 and the second cooling unit 220. The heat dissipation component 230 dissipates heat from the heat dissipation medium M through heat convection. The pump 260 is configured to assist the flow of the heat dissipation medium M in the pipeline component 240.

The liquid cooling module 200 of this embodiment may further be configured to cool the light valve module 150. The liquid cooling module 200 further includes a third cooling unit 250. The third cooling unit 250 is configured to dissipate heat for the light valve module 150. The pipeline component 240 is connected to the third cooling unit 250 to transport the heat dissipation medium M to the third cooling unit 250. The heat dissipation medium M performs heat exchange with the light valve module 150 through heat conduction in the third cooling unit 250. The first cooling unit 210, the second cooling unit 220, and the third cooling unit 250 are, for example, cooling plate bodies with internal flow paths.

As shown in FIG. 2 and FIG. 3, the first cooling unit 210 includes a first communication surface 212 and a first cooling surface 214 opposite to the first communication surface 212. The first cooling surface 214 is connected to the first heat source 112 of the lighting module 110 and is configured to conduct the heat generated by the first heat source 112 to the first cooling surface 214 to dissipate heat from the first heat source 112. The first communication surface 212 is connected to the pipeline component 240. The second cooling unit 220 includes a top surface 223, a second communication surface 222, and a second cooling surface 224. The top surface 223 is perpendicular to the first communication surface 212 and opposite to the second cooling surface 224. The second cooling surface 224 is connected to the second heat source 114 of the lighting module 110 and is configured to conduct the heat generated by the second heat source 114 to the second cooling surface 224 to dissipate heat from the second heat source 114. The second communication surface 222 is connected to the pipeline component 240.

The third cooling unit 250 includes a third communication surface 252 and a third cooling surface 254. The third cooling surface 254 of the third cooling unit 250 is connected to the light valve module 150 and is configured to conduct the heat generated by the light valve module 150 to the third cooling surface 254 to dissipate heat from the light valve module 150. The third communication surface 252 is connected to the pipeline component 240.

FIG. 3 schematically illustrates the flow direction of the heat dissipation medium M in the pipeline component 240 with arrows. The heat dissipation medium M is, for example, water or a cooling liquid. As shown in FIG. 3, the heat dissipation medium M flows from the heat dissipation component 230 to the pump 260, the first cooling unit 210, the second cooling unit 220, and the third cooling unit 250 in sequence, and then flows back to the heat dissipation component 230. The pipeline component 240 includes a first pipeline 241, a second pipeline 244, and a third pipeline 245. The first pipeline 241 is connected to the heat dissipation component 230 and the first communication surface 212 of the first cooling unit 210. The second pipeline 244 is connected to the first communication surface 212 and the second communication surface 222 of the second cooling unit 220, and the third pipeline 245 is connected to the second communication surface 222 and the heat dissipation component 230.

The first pipeline 241 includes a first sub-pipeline 242 and a second sub-pipeline 243. The first sub-pipeline 242 is connected to the heat dissipation component 230 and the pump 260, and the second sub-pipeline 243 is connected to the pump 260 and the first communication surface 212 of the first cooling unit 210. The third pipeline 245 includes a third sub-pipeline 246 and a fourth sub-pipeline 247. The third sub-pipeline 246 is connected to the second cooling unit 220 (e.g., the second communication surface 222) and the third cooling unit 250 (e.g., the third communication surface 252). The fourth sub-pipeline 247 is connected to the third cooling unit 250 and the heat dissipation component 230.

As shown in FIG. 3, FIG. 4, and FIG. 5, the heat dissipation component 230 includes a heat sink 232 and a water tank 234. The heat sink 232 is connected to the water tank 234. In this embodiment, the heat sink 232 and the water tank 234 are integrally formed, but not limited thereto. The heat sink 232 may include fins, but not limited thereto. The heat sink 232 is configured to dissipate heat from the heat dissipation medium M. The heat dissipation medium M, after being dissipated by the heat sink 232, flows into and is stored in the water tank 234. In addition, the water inlet of the heat sink 232 is connected to the fourth sub-pipeline 247, the water outlet of the heat sink 232 is connected to the water inlet of the water tank 234, and both the water inlet and the water outlet of the heat sink 232 are located on the same side of the heat sink 232, which is designed to reduce the space required for the pipeline component 240. Furthermore, the bottom surface 233 of the heat sink 232 and the bottom surface 235 of the water tank 234 are not aligned in the gravity direction G to form the first space S1. In other words, the first space S1 is formed between the bottom portion 126 of the casing 120 and the bottom surface 235 of the water tank 234. A portion of the third pipeline 245 (e.g., a portion of the fourth sub-pipeline 247) passes through the first space S1 and is connected to the heat sink 232. Specifically, in the gravity direction G, a portion of the fourth sub-pipeline 247 is located between the bottom surface 235 of the water tank 234 and the bottom portion 126 of the casing 120. In addition, the first sub-pipeline 242 of the first pipeline 241 is connected to the water tank 234 for guiding the heat dissipation medium M to flow into the pump 260.

As shown in FIG. 2 and FIG. 5, the projection device 100 further includes a power module 170. In the gravity direction G, the power module 170 is located between the lens module 160 and the bottom portion 126 of the casing 120, thereby further reducing the total volume of the projection device 100. The projection device 100 further includes at least one intake fan 130 and at least one exhaust fan 140. In this embodiment, the number of intake fans 130 is two, and the number of exhaust fans 140 is two. The intake fan 130 and the exhaust fan 140 are located in the casing 120. The casing 120 includes at least one air inlet 122 and at least one air outlet 124. The intake fan 130 and the exhaust fan 140 are configured to form the airflow C. The heat sink 232 of the heat dissipation component 230 is located between the air inlet 122 and the intake fan 130 and is located on the path of the airflow C. The heat sink 232 of the heat dissipation component 230 is configured to perform heat exchange with the airflow C to dissipate the heat energy of the heat dissipation medium M. The exhaust fan 140 is positioned on the path of the airflow C, between the air outlet 124 and the lens module 160. The airflow C enters the casing 120 from the air inlet 122, flows through the heat sink 232, the intake fan 130, the power module 170, the lens module 160, and the exhaust fan 140, and leaves the casing 120 through the air outlet 124.

As shown in FIG. 2 and FIG. 3, the heat dissipation medium M performs heat exchange with the airflow C through the heat sink 232 to dissipate the heat energy of the heat dissipation medium M. After heat dissipation, the heat dissipation medium M with low heat energy flows into the water tank 234. Subsequently, the pump 260 extracts the heat dissipation M from the water tank 234, causing the heat dissipation medium M with low heat energy to flow from the water tank 234 into the first sub-pipeline 242 (the first pipeline 241) and flow into the second sub-pipeline 243 through the pump 260. The heat dissipation medium M with low heat energy flows into the first cooling unit 210 through the second sub-pipeline 243.

The first cooling unit 210 includes a first water inlet 216 and a first water outlet 217. The first water inlet 216 and the first water outlet 217 are located on the first communication surface 212. The first water inlet 216 is connected to the first pipeline 241 (second sub-pipeline 243), and the first water outlet 217 is connected to the second pipeline 244. The heat dissipation medium M flows into the internal flow channel of the first cooling unit 210 from the first water inlet 216 and leaves the first cooling unit 210 from the first water outlet 217. The first water inlet 216 and the first water outlet 217 are not aligned in the gravity direction G. In this embodiment, in the gravity direction G, the first water inlet 216 is disposed between the first water outlet 217 and the bottom portion 126 of the casing 120, so that the heat dissipation medium M flows more uniformly within the internal channel of the first cooling unit 210, thereby the temperature of the first cooling surface 214 is more uniform, and the first heat source 112 may be uniformly cooled.

After the heat dissipation medium M performs heat exchange with the first heat source 112 through the first cooling surface 214, the heat dissipation medium M flows into the second pipeline 244 through the first water outlet 217. The heat dissipation medium M flows to the second communication surface 222 of the second cooling unit 220 through the second pipeline 244.

As shown in FIG. 2 and FIG. 5, the second cooling unit 220 of this embodiment includes a side surface 225. The second communication surface 222 is the side surface 225. The casing 120 has a top portion 125 and a bottom portion 126 opposite to each other. The bottom portion 126 is located below the top portion 125 in the gravity direction G. In the gravity direction G, a second space S2 is formed between the first cooling unit 210 and the bottom portion 126 and between the second cooling unit 220 and the bottom portion 126. A portion of the second pipeline 244 is disposed in the second space S2, and the second pipeline 244 passes through the second space S2 and is connected to the second communication surface 222 (side surface 225). Since the second communication surface 222 (side surface 225) is connected between the top surface 223 and the second cooling surface 224, and the second communication surface 222 (side surface 225) is away from the first communication surface 212, the length of the second pipeline 244 connected to the first communication surface 212 and the second communication surface 222 is longer.

The longer second pipeline 244 may effectively reduce the stress caused by the heat dissipation medium M on the second pipeline 244, thereby preventing the second pipeline 244 from pulling the first cooling unit 210 and the second cooling unit 220, resulting in a relative deviation of the first cooling unit 210 and the second cooling unit 220. This also prevents the light path deviation of the light beam 502 from the first heat source 112 (light source device) and the light path deviation of the light beam 504 from the second heat source 114 (light source device). Thereby, the first cooling surface 214 of this embodiment may be perpendicular to the second cooling surface 224 to ensure that the first heat source 112 and the second heat source 114 remain perpendicular to each other.

As shown in FIG. 2 and FIG. 3, the second cooling unit 220 further includes a second water inlet 226 and a second water outlet 227. The second water inlet 226 and the second water outlet 227 are located on the side surface 225 (second communication surface 222). The second water inlet 226 is connected to the second pipeline 244, and the second water outlet 227 is connected to the third pipeline 245 (third sub-pipeline 246). The heat dissipation medium M flows into the internal flow channel of the second cooling unit 220 from the second water inlet 226 and leaves the second cooling unit 220 from the second water outlet 227.

The second water inlet 226 and the second water outlet 227 are not aligned in the gravity direction G, so that the heat dissipation medium M may flow in the second cooling unit 220 more uniformly, and the second heat source 114 may be cooled uniformly. After the heat dissipation medium M performs heat exchange with the second heat source 114 through the second cooling surface 224, the heat dissipation medium M flows into the third sub-pipeline 246 through the second water outlet 227 and then flows to the third cooling unit 250.

In this embodiment, the distance (the shortest distance) between the first cooling unit 210 and the lens module 160 is less than the distance between the second cooling unit 220 and the lens module 160.

As shown in FIG. 3, the third cooling unit 250 further includes a third water inlet 256 and a third water outlet 257. The third communication surface 252 of this embodiment is specifically the two side surfaces 255a and 255b of the third cooling unit 250. The third communication surface 252 (side surfaces 255a and 255b) is connected to the third cooling surface 254, but not limited thereto. The third water inlet 256 is located on the side surface 255a, the third water outlet 257 is located on the side surface 255b, and the two side surfaces 255a and 255b are opposite to each other. The heat dissipation medium M flows into the internal flow channel of the third cooling unit 250 through the third sub-pipeline 246. After the heat dissipation medium M carries out heat exchange with the light valve module 150 through the third cooling surface 254, the heat dissipation medium M flows into the fourth sub-pipeline 247 of the third pipeline 245 through the third water outlet 257.

The heat dissipation medium M flows into the heat dissipation component 230 (heat sink 232) through the fourth sub-pipeline 247 to dissipate heat through the heat sink 232, and the heat dissipation medium M flows into the water tank 234 after heat dissipation. At this point, the heat dissipation medium M completes a heat dissipation cycle. During a heat dissipation cycle, the heat dissipation medium M sequentially performs heat exchange on the first heat source 112, the second heat source 114, and the light valve module 150. In other words, the heat dissipation medium M located in the first cooling unit 210 has less heat energy than the heat dissipation medium M located in the second cooling unit 220, and the heat dissipation medium M located in the second cooling unit 220 has less heat energy than the heat dissipation medium M located in the third cooling unit 250.

Therefore, the first heat source 112 is connected to the first cooling unit 210 so that the heat dissipation medium M first performs heat exchange with the first heat source 112 in each heat dissipation cycle to ensure that the first heat source 112 may be cooled to the target temperature. After the first heat source 112 is cooled to the target temperature, the heat dissipation medium M sequentially cools the second heat source 114 and the light valve module 150 so that the second heat source 114 and the light valve module 150 are cooled to the target temperature.

In this embodiment, the airflow C, formed by the heat dissipation component 230, the intake fan 130, and the exhaust fan 140, may effectively cool down the heat dissipation medium M, as well as the components inside the projection device 100, so that the number of fans (intake fan 130 and exhaust fan 140) required by the projection device 100 is reduced and the fan speed is decreased, thereby reducing the volume of the projection device 100 and lowering the noise generated by the fans.

In this embodiment, the target temperature of the first heat source 112 is approximately 44 degrees Celsius (° C.), the target temperature of the second heat source 114 is approximately 46 degrees Celsius, and the target temperature of the light valve module 150 is approximately 47 degrees Celsius. According to actual test results, under the condition where the heat loading of the first heat source 112 is about 124 watts (W), the heat loading of the second heat source 114 is about 79 watts, and the heat loading of the light valve module 150 is about 40 watts, the liquid cooling module 200 may cool the first heat source 112 to about 43 degrees Celsius, the second heat source 114 to about 43 degrees Celsius, and the light valve module 150 to about 43 degrees Celsius. It may be seen that the liquid cooling module 200 may effectively cool the first heat source 112, the second heat source 114, and the light valve module 150 to the target temperature, and the liquid cooling module 200 and the projection device 100 have good heat dissipation performance.

Compared to the known projection devices, the overall volume of the projection device 100 in this embodiment is reduced by 6%, and the noise generated by the intake fan 130 and exhaust fan 140 is reduced by approximately 2˜3 dB, thereby achieving a noise reduction effect.

In addition, the pump 260 of the liquid cooling module 200 generates vibration during operation. The vibration of the pump 260 is transmitted through the pipeline component 240 and absorbed by the pipeline component 240, in order to prevent the light valve module 150 from being affected by vibration and causing a pixel shift, that is, shakes generated in the projected image. In this embodiment, the light valve module 150 is connected to the third cooling unit 250. The vibration of the pump 260, during its transmission through the pipeline component 240, is absorbed by the first pipeline 241, the second pipeline 244, and the third sub-pipeline 246. This may prevent the vibration of the pump 260 from being transmitted to the third cooling unit 250 and affecting the light valve module 150.

In addition, as shown in FIG. 3, the outer casing of the water tank 234 may include a fin structure 236, and the heat dissipation medium M stored in the water tank 234 may further dissipate heat energy through the fin structure 236, to improve the cooling performance of the heat dissipation component 230 and the heat dissipation performance of the liquid cooling module 200. Since the heat energy of the heat dissipation medium M is reduced, the fan speeds of the intake fan 130 and the exhaust fan 140 may be reduced to further reduce the noise of the intake fan 130 and the exhaust fan 140. In addition, the temperature of the heat dissipation medium M may also be lowered, the problem of the heat dissipation medium M being lost due to pipelines may be improved (i.e., the evaporation rate may be improved), and the service life of the liquid cooling module 200 may be extended.

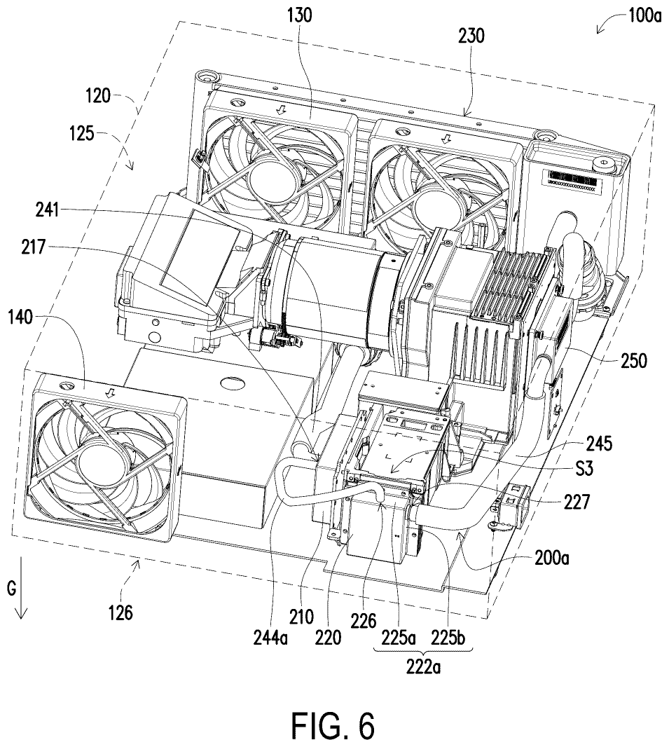

FIG. 6 is a schematic diagram of a projection device according to another embodiment of the disclosure. It is worth mentioning that the projection device 100a has two exhaust fans 140, but the drawing of one exhaust fan 140 is omitted herein to avoid obscuring the components inside the projection device 100a. Referring to FIG. 5 and FIG. 6 at the same time, the projection device 100a of this embodiment is similar to the previous embodiment. The difference between the two is that the diameter of the second pipeline 244a in this embodiment is different from the diameter of the first pipeline 241. The diameter of the second pipeline 244a is less than the diameter of the first pipeline 241, and the diameter of the second pipeline 244a is less than the diameter of the third pipeline 245. The second cooling unit 220 includes two side surfaces 225a and 225b, and the second communication surface 222a is the two side surfaces 225a and 225b. The second water inlet 226 and the second water outlet 227 are located on the second communication surface 222a (two side surfaces 225a and 225b). The second water inlet 226 is located on the side surface 225a, and the second water outlet 227 is located on the side surface 225b.

As shown in FIG. 6, in the gravity direction G, a third space S3 is formed between the first cooling unit 210 and the top portion 125 of the casing 120, and between the second cooling unit 220 and the top portion 125 of the casing 120. A portion of the second pipeline 244a is disposed in the third space S3, and the second pipeline 244a passes through the third space S3 and is connected to the second communication surface 222a (side surface 225a). By reducing the diameter of the second pipeline 244a, the volume of the projection device 100a of this embodiment may be further reduced. Compared with the known projection device, the volume of the projection device 100a of this embodiment is reduced by 13%. The projection device 100a of this embodiment has the same effect as the previous embodiment, and is not repeated herein.

To sum up, in the liquid cooling module and the projection device using the liquid cooling module of the disclosure, the first cooling module is configured to cool the first heat source, and the second cooling unit is configured to cool the second heat source. The second pipeline of the pipeline component is connected to the first communication surface of the first cooling unit and the second communication surface of the second cooling unit. The first communication surface and the second communication surface do not affect each other, and the first communication surface is perpendicular to the top surface of the second cooling unit. By transporting the heat dissipation medium through the pipeline component, the liquid cooling module and the projection device may cool the lighting module through liquid cooling, which has good heat dissipation performance and may reduce the volume of the liquid cooling module and the projection device.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A liquid cooling module, configured to cool a lighting module, the liquid cooling module comprising:
a first cooling unit, comprising a first communication surface and a first cooling surface opposite to the first communication surface, the first cooling surface connecting to a first heat source of the lighting module;
a second cooling unit, comprising a top surface, a second communication surface, and a second cooling surface, wherein the top surface is perpendicular to the first communication surface and opposite to the second cooling surface, and the second cooling surface is connected to a second heat source of the lighting module;
a heat dissipation component, configured to dissipate heat from a heat dissipation medium; and
a pipeline component, the heat dissipation medium flowing in the pipeline component, the pipeline component comprising a first pipeline, a second pipeline and a third pipeline, the first pipeline connecting to the heat dissipation component and the first communication surface, the second pipeline connecting to the first communication surface and the second communication surface, the third pipeline connecting to the second communication surface and the heat dissipation component.

2. The liquid cooling module according to claim 1, wherein the first cooling unit comprises a first water inlet and a first water outlet, the first water inlet and the first water outlet are located on the first communication surface, the first water inlet and the first water outlet are not aligned in a gravity direction, the first water inlet is connected to the first pipeline, and the first water outlet is connected to the second pipeline.

3. The liquid cooling module according to claim 1, further comprising a pump, the first pipeline comprising a first sub-pipeline and a second sub-pipeline, the first sub-pipeline connecting to the heat dissipation component and the pump, the second sub-pipeline connecting to the pump and the first communication surface of the first cooling unit.

4. The liquid cooling module according to claim 1, wherein the liquid cooling module is further configured to cool a light valve module, the liquid cooling module further comprises a third cooling unit, the third pipeline comprises a third sub-pipeline and a fourth sub-pipeline, the third sub-pipeline is connected to the second cooling unit and the third cooling unit, the fourth sub-pipeline is connected to the third cooling unit and the heat dissipation component, the third cooling unit is connected to the light valve module.

5. The liquid cooling module according to claim 1, wherein the heat dissipation component comprises a heat sink, and a water tank, the heat sink is connected to the water tank, a bottom surface of the heat sink and a bottom surface of the water tank are not aligned in a gravity direction to form a first space, a portion of the third pipeline is disposed in the first space and connected to the heat sink, and the first pipeline is connected to the water tank.

6. The liquid cooling module according to claim 5, wherein the heat sink and water tank are integrally formed.

7. The liquid cooling module according to claim 5, wherein the water tank comprises a fin structure.

8. The liquid cooling module according to claim 1, wherein the second cooling unit comprises a side surface, a second water inlet, and a second water outlet, the second communication surface is the side surface, the second water inlet and the second water outlet are located on the side surface, the second water inlet and the second water outlet are not aligned in a gravity direction.

9. The liquid cooling module according to claim 1, wherein the second cooling unit comprises two side surfaces, a second water inlet, and a second water outlet, the second communication surface is the two side surfaces, the second water inlet and the second water outlet are located on the second communication surface, the second water inlet is located on one of the two side surfaces, the second water outlet is located on another one of the two side surfaces.

10. The liquid cooling module according to claim 9, wherein a diameter of the second pipeline is less than a diameter of the first pipeline, and the diameter of the second pipeline is less than a diameter of the third pipeline.

11. A projection device, comprising:
a lighting module, configured to provide an illumination beam, the lighting module comprising a first heat source and a second heat source;
a light valve module, disposed on a transmission path of the illumination beam to convert the illumination beam into an image beam;
a lens module, disposed on a transmission path of the image beam to project the image beam; and
a liquid cooling module, comprising:
a first cooling unit, comprising a first communication surface and a first cooling surface opposite to each other, the first cooling surface connecting to the first heat source;
a second cooling unit, comprising a top surface, a second communication surface, and a second cooling surface, wherein the top surface is perpendicular to the first communication surface and opposite to the second cooling surface, and the second cooling surface is connected to the second heat source;
a heat dissipation component, configured to dissipate heat from a heat dissipation medium; and
a pipeline component, the heat dissipation medium flowing in the pipeline component, the pipeline component comprising a first pipeline, a second pipeline, and a third pipeline, the first pipeline connecting to the heat dissipation component and the first communication surface, the second pipeline connecting to the first communication surface and the second communication surface, the third pipeline connecting to the second communication surface and the heat dissipation component.

12. The projection device according to claim 11, wherein the first cooling unit comprises a first water inlet and a first water outlet, the first water inlet and the first water outlet are located on the first communication surface, the first water inlet and the first water outlet are not aligned in a gravity direction, the first water inlet is connected to the first pipeline, and the first water outlet is connected to the second pipeline.

13. The projection device according to claim 11, wherein the liquid cooling module further comprises a pump, the first pipeline comprises a first sub-pipeline and a second sub-pipeline, the first sub-pipeline is connected to the heat dissipation component and the pump, the second sub-pipeline is connected to the pump and the first communication surface of the first cooling unit.

14. The projection device according to claim 11, wherein the first heat source and second heat source are both light source devices, the first heat source and the second heat source are configured to provide a plurality of light beams, the lighting module further comprises a light combining component, the light combining component is located at a position that receives the light beams, the light combining component is configured to guide the light beams to form an illumination beam.

15. The projection device according to claim 14, the liquid cooling module further comprising a third cooling unit, the third pipeline comprising a third sub-pipeline and a fourth sub-pipeline, the third sub-pipeline connecting to the second cooling unit and the third cooling unit, the fourth sub-pipeline connecting to the third cooling unit and the heat dissipation component, the third cooling unit connecting to the light valve module for cooling the light valve module.

16. The projection device according to claim 11, wherein the heat dissipation component comprises a heat sink and a water tank, the heat sink is connected to the water tank, a bottom surface of the heat sink and a bottom surface of the water tank are not aligned in a gravity direction to form a first space, a portion of the third pipeline is disposed in the first space and connected to the heat sink, the first pipeline is connected to the water tank.

17. The projection device according to claim 11, wherein the second cooling unit comprises a side surface, a second water inlet, and a second water outlet, the second communication surface is the side surface, the second water inlet and the second water outlet are located on the side surface, the second water inlet and the second water outlet are not aligned in a gravity direction.

18. The projection device according to claim 11, wherein the second cooling unit comprises two side surfaces, a second water inlet, and a second water outlet, the second water inlet and the second water outlet are located on the second communication surface, the second communication surface is the two side surfaces, the second water inlet is located on one of the two side surfaces, and the second water outlet is located on another one of the two side surfaces.

19. The projection device according to claim 11, further comprising a casing, at least one intake fan, and at least one exhaust fan, wherein the liquid cooling module, the lighting module, the light valve module, the at least one intake fan, and the at least one exhaust fan are located in the casing, the casing comprises at least one air inlet and at least one air outlet, the at least one intake fan and the at least one exhaust fan are configured to form airflow, the heat dissipation component is located on a path of the airflow for heat exchange with the airflow, the airflow enters the casing from the at least one air inlet and leaves the casing from the at least one air outlet.

20. The projection device according to claim 19, wherein the heat dissipation component is located between the at least one air inlet and the at least one intake fan.

21. The projection device according to claim 11, further comprising a power module and a casing, wherein the casing has a bottom portion, and the power module is located between the lens module and the bottom portion in a gravity direction.

22. The projection device according to claim 11, further comprising a casing, wherein the casing has a bottom portion, in a gravity direction, a second space is formed between the first cooling unit and the bottom portion and between the second cooling unit and the bottom portion, a portion of the second pipeline is disposed in the second space.
